(19) United States
(12) Patent Application Publication
(10) Pub. No.: US 2026/0239852 A1
(43) Pub. Date: Aug. 13, 2026

(54) DISPLAY PANEL AND DISPLAY DEVICE

(71) Applicants: Hefei BOE Joint Technology Co., Ltd., Hefei (CN); BOE TECHNOLOGY GROUP CO., LTD., Beijing (CN); Beijing BOE Technology Development Co., Ltd., Beijing (CN)

(72) Inventors: Wenbin JIA, Beijing (CN); Huifeng WANG, Beijing (CN); Minghung HSU, Beijing (CN); Zhijie YE, Beijing (CN)

(73) Assignees: Hefei BOE Joint Technology Co., Ltd., Hefei (CN); BOE TECHNOLOGY GROUP CO., LTD., Beijing (CN); Beijing BOE Technology Development Co., Ltd., Beijing (CN)

(21) Appl. No.: 19/470,809

(22) PCT Filed: Sep. 24, 2024
(86) PCT No.: PCT/CN2024/120716

§ 371 Date: Sep. 30, 2025

(30) Foreign Application Priority Data
Oct. 25, 2023 (CN) 202311394838.9

(51) Int. Cl. H10K 59/38; H10K 59/80

(52) U.S. Cl. CPC H10K 59/38; H10K 59/80518; H10K 59/878

(57) ABSTRACT

A display panel includes a light-emitting layer and a filter layer. The light-emitting layer includes a plurality of light-emitting portions distributed in an array that include at least a light-emitting portion for emitting white light. The filter layer is located on a light-exit side of the light-emitting layer and includes a plurality of filter portions corresponding one-to-one to the plurality of light-emitting portions. The plurality of filter portions include a first filter portion, a second filter portion, a third filter portion and a fourth filter portion, and a light-emitting portion corresponding to the fourth filter portion is for emitting the white light. In a direction perpendicular to the display panel, the first filter portion, the second filter portion and the third filter portion all cover corresponding light-emitting portions, and the fourth filter portion at least partially overlaps with a corresponding light-emitting portion.

### CROSS-REFERENCE TO RELATED APPLICATION(S)

This application is a national phase entry under 35 USC 371 of International Patent Application No. PCT/CN2024/120716, filed on Sep. 24, 2024, which claims priority to Chinese Patent Application No. 202311394838.9, titled “DISPLAY PANEL AND DISPLAY DEVICE”, filed on Oct. 25, 2023, each are incorporated herein by reference in their entirety.

### TECHNICAL FIELD

The present disclosure relates to the field of display technologies, and in particular, to a display panel and a display device.

### BACKGROUND

With the continuous development of display technologies, people have higher and higher requirements on image quality (e.g., color gamut) of display devices. For example, in the related art, a display device may realize full-color display through a filter layer.

It will be noted that the information disclosed in the background section above is only used to enhance understanding of the background of the present disclosure, and therefore may include information that does not constitute the prior art known to those ordinary skill in the art.

### SUMMARY

In an aspect of the present disclosure, a display panel is provided and includes:
a light-emitting layer including a plurality of light-emitting portions distributed in an array, the plurality of light-emitting portions including at least a light-emitting portion for emitting white light; and
a filter layer located on a light-exit side of the light-emitting layer and including a plurality of filter portions corresponding one-to-one to the plurality of light-emitting portion.

The plurality of filter portions include a first filter portion, a second filter portion, a third filter portion and a fourth filter portion, and a light-emitting portion corresponding to the fourth filter portion is for emitting the white light. In a direction perpendicular to the display panel, the first filter portion, the second filter portion and the third filter portion all cover corresponding light-emitting portions, and the fourth filter portion at least partially overlaps with a corresponding light-emitting portion. The first filter portion is configured to allow a first color light to exit, the second filter portion is configured to allow a second color light to exit, the third filter portion is configured to allow a third color light to exit, and the fourth filter portion is configured to allow the white light to exit.

In accordance with any display panel in the present disclosure, the fourth filter portion includes a first filter sub-portion, and light exit from the first filter sub-portion has a same color as light exit from the second filter portion.

In accordance with any display panel in the present disclosure, the first filter sub-portion is disposed in a same layer and made of a same material as the second filter portion.

In accordance with any display panel in the present disclosure, in a case where a ratio of an area of the first filter sub-portion to an area of a light-emitting region of the light-emitting portion corresponding to the fourth filter portion is greater than or equal to a reference value, a thickness of the first filter sub-portion is less than a thickness of the second filter portion.

In a case where the ratio of the area of the first filter sub-portion to the area of the light-emitting region of the light-emitting portion corresponding to the fourth filter portion is less than the reference value, the thickness of the first filter sub-portion is greater than or equal to the thickness of the second filter portion.

In accordance with any display panel in the present disclosure, the fourth filter portion further includes a second filter sub-portion, and light exit from the second filter sub-portion has a same color as light exit from the first filter portion; and the first filter sub-portion and the second filter sub-portion are distributed in a same layer or in stacked layers.

In accordance with any display panel in the present disclosure, the fourth filter portion includes a third filter sub-portion, and light exit from the third filter sub-portion has a same color as mixed light of light exit from the first filter portion and light exit from the second filter portion.

In accordance with any display panel in the present disclosure, in a case where a ratio of an area of the third filter sub-portion to an area of a light-emitting region of the light-emitting portion corresponding to the fourth filter portion is greater than or equal to a reference value, a thickness of the third filter sub-portion is less than a thickness of the first filter portion and less than a thickness of the second filter portion.

In a case where the ratio of the area of the third filter sub-portion to the area of the light-emitting region of the light-emitting portion corresponding to the fourth filter portion is less than the reference value, the thickness of the third filter sub-portion is greater than or equal to the thickness of the first filter portion and greater than or equal to the thickness of the second filter portion.

In accordance with any display panel in the present disclosure, the fourth filter portion further includes a fourth filter sub-portion, and light exit from the fourth filter sub-portion has a same color as light exit from the third filter portion; and the first filter sub-portion, the second filter sub-portion and the fourth filter sub-portion are distributed in the same layer, or at least two filter sub-portions are distributed in stacked layers.

In accordance with any display panel in the present disclosure, the first filter portion, the second filter portion and the third filter portion are for emitting red light, green light and blue light, respectively.

In accordance with any display panel in the present disclosure, an area ratio of the first filter sub-portion, the second filter sub-portion and the fourth filter sub-portion is 7:2:1.

In accordance with any display panel in the present disclosure, a thickness ratio of the first filter sub-portion, the second filter sub-portion and the fourth filter sub-portion is 7:2:1.

In accordance with any display panel in the present disclosure, the plurality of light-emitting portions include reflective anodes, and reflectivity of a reflective anode corresponding to the first filter portion, reflectivity of a reflective anode corresponding to the second filter portion and reflectivity of a reflective anode corresponding to the third filter portion are all greater than reflectivity of a reflective anode corresponding to the fourth filter portion.

In accordance with any display panel in the present disclosure, the reflective anode corresponding to the first filter portion, the reflective anode corresponding to the second filter portion, and the reflective anode corresponding to the third filter portion are all composite layers of silver and indium tin oxide or all composite layers of nickel-aluminum alloy and indium tin oxide, and the reflective anode corresponding to the fourth filter portion is a composite layer of molybdenum and indium tin oxide.

In accordance with any display panel in the present disclosure, the plurality of light-emitting portions include a first light-emitting portion corresponding to the first filter portion, a second light-emitting portion corresponding to the second filter portion, a third light-emitting portion corresponding to the third filter portion, and a fourth light-emitting portion corresponding to the fourth filter portion; and the fourth light-emitting portion is configured to emit the white light.

In accordance with any display panel in the present disclosure, each light-emitting portion includes an anode, a light-emitting functional layer and a cathode. A light-emitting functional layer included in the light-emitting portion for emitting the white light has a film layer structure in which a red functional layer, a green functional layer and a blue functional layer are stacked in sequence; alternatively, a light-emitting functional layer included in the light-emitting portion for emitting the white light has a film layer structure in which a blue functional layer, a red functional layer, a yellow functional layer and a blue functional layer are stacked in sequence.

In accordance with any display panel in the present disclosure, the display panel further includes a light-shielding layer. The light-shielding layer is located in a same layer as the filter layer, and the light-shielding layer is distributed between two adjacent filter portions to separate the plurality of filter portions.

In accordance with any display panel in the present disclosure, the display panel further includes a thin film encapsulation layer. The thin film encapsulation layer is disposed on a side of the filter layer proximate to the light-emitting layer, or on a side of the filter layer away from the light-emitting layer. The thin film encapsulation layer includes an inorganic encapsulation layer, an organic encapsulation layer and an inorganic encapsulation layer that are disposed alternately.

In an aspect of the present disclosure, a display device is provided. The display device includes the display panel as described in the above aspect.

It should be understood that the foregoing general description and the following detailed description are merely exemplary and explanatory and do not limit the present disclosure.

### BRIEF DESCRIPTION OF THE DRAWINGS

The accompanying drawings here, which are incorporated into the specification and constitute a part of the specification, show embodiments of the present disclosure, and are used together with the specification to explain the principle of the present disclosure. Obviously, the accompanying drawings to be described below are merely drawings of some embodiments of the present disclosure, and a person of ordinary skilled in the art may obtain other drawings according to these drawings without paying any creative effort.

FIG. 1 is a top view of a partial structure of a display panel provided in the related art;

FIG. 2 is a sectional view of a structure of the display panel in FIG. 1 taken along an A-A line;

FIG. 3 is a curve graph of reflectivity of three light-emitting portions in the display panel in FIG. 1 in an anode light-emitting reflective region;

FIG. 4 is a curve graph of reflectivity of the display panel in FIG. 1 in a light-shielding reflective region;

FIG. 5 is a curve graph of reflectivity of four light-emitting portions in the display panel in FIG. 1 in an anode edge reflective region;

FIG. 6 is a top view of a partial structure of a display panel provided in embodiments of the present disclosure;

FIG. 7 is a sectional view of a structure of the display panel in FIG. 6 taken along a B-B line;

FIG. 8 is a top view of a partial structure of another display panel provided in embodiments of the present disclosure;

FIG. 9 is a sectional view of a partial structure of another display panel provided in embodiments of the present disclosure;

FIG. 10 is a top view of a partial structure of another display panel provided in embodiments of the present disclosure; and

FIG. 11 is a sectional view of a partial structure of another display panel provided in embodiments of the present disclosure.

### DESCRIPTION OF REFERENCE NUMERALS

1. base substrate; 2. light-emitting layer; 3. filter layer; 4. light-shielding layer; 5. thin film encapsulation layer;
11. substrate; 12. driving layer;
21. first light-emitting portion; 22. second light-emitting portion; 23. third light-emitting portion; 24. fourth light-emitting portion; 25. light-transmitting region;
211, anode; 212, light-emitting functional layer; 213, cathode; 214, pixel definition layer;
215, reflective anode; 216, blue functional layer; 217, red functional layer; 218, yellow functional layer;
31. first filter portion; 32. second filter portion; 33. third filter portion; 34. fourth filter portion;
341. first filter sub-portion; 342. second filter sub-portion; 343. fourth filter sub-portion;
AA. anode light-emitting reflective region; BB. anode edge reflective region; CC light-shielding reflective region.

### DETAILED DESCRIPTION

Exemplary embodiments will now be described more fully with reference to the accompanying drawings. However, the exemplary embodiments can be implemented in various forms, and should not be construed as being limited to the examples set forth here; on the contrary, the provision of these embodiments makes the present disclosure more comprehensive and complete, and fully conveys the concept of the exemplary embodiments to those skilled in the art. The same reference numerals in the drawings denote the same or similar structures, and thus their repeated description will be omitted. In addition, the drawings are merely schematic illustrations of the present disclosure and are not necessarily drawn to scale.

Although relative terms such as “upper” and “lower” are used in the specification to describe a relative relationship of a component to another component in the drawing, these terms are used in the specification only for convenience, for example, based on directions of examples described in the drawings. It will be understood that if a device in the drawing is turned upside down, the “upper” component as described will become a “lower” component. In a case where a structure is “on” another structure, it may mean that the structure is integrally formed on the another structure, or that the structure is “directly” provided on the another structure, or that the structure is “indirectly” provided on the another structure through yet another structure.

The terms “a”, “an”, “the”, “said” and “at least one” are used to indicate the presence of one or more elements/components/etc. The terms “including” and “having” are used to indicate an open inclusion and mean that there may be additional elements/components/etc. in addition to the listed elements/components/etc. The terms “first”, “second”, “third” and the like are used only as labels and are not intended to limit the quantity of the objects.

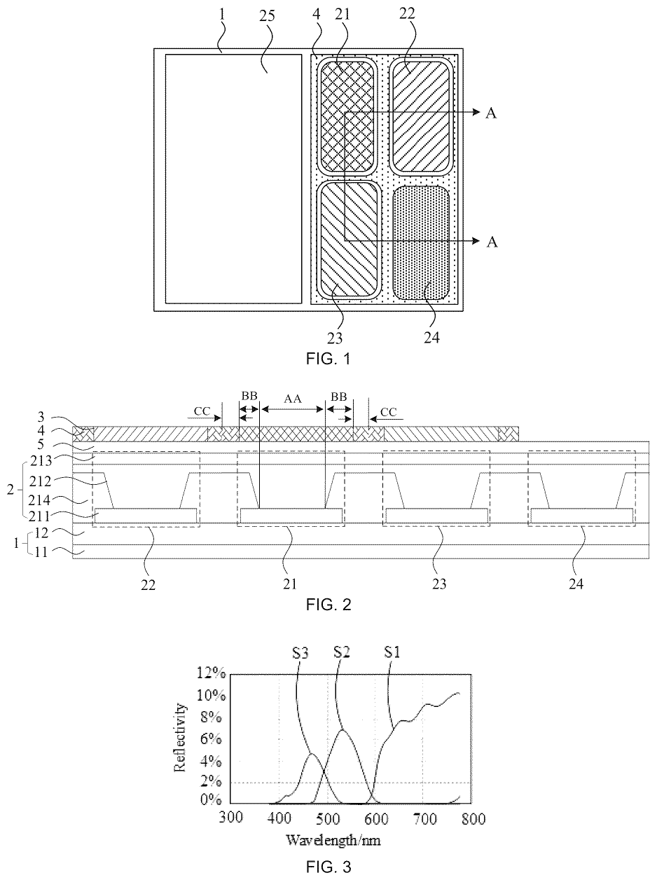

FIG. 1 illustrates a top view of a partial structure of a display panel in the related art, and FIG. 2 illustrates a sectional view of a structure of the display panel in FIG. 1 taken along an A-A line. As shown in FIGS. 1 and 2, the display panel includes a light-emitting layer 2, and a filter layer 3 and a light-shielding layer 4 that are located on a light-exit side of the light-emitting layer 2. The light-emitting layer 2 includes a plurality of light-emitting portions for emitting white light, and the filter layer 3 includes a plurality of filter portions (e.g., a red filter portion, a green filter portion and a blue filter portion). The plurality of filter portions are used to filter the white light entering them to allow lights of three primary colors for color display to pass through (the red filter portion may only allow red light to pass through, the green filter portion may only allow green light to pass through, and the blue filter portion may only allow blue light to pass through). The light-shielding layer 4 has a function of absorbing light in all visible bands. The light-shielding layer 4 is distributed between any two adjacent filter portions to separate the plurality of filter portions, so as to prevent cross-color between different filter portions and avoid affecting the display effect.

The plurality of light-emitting portions include a first light-emitting portion 21 corresponding to the red filter portion, a second light-emitting portion 22 corresponding to the green filter portion, a third light-emitting portion 23 corresponding to the blue filter portion and a fourth light-emitting portion 24. The red filter portion covers the corresponding first light-emitting portion 21 and allows red light in the white light emitted by the first light-emitting portion 21 to pass through. The green filter portion covers the corresponding second light-emitting portion 22 and allows green light in the white light emitted by the second light-emitting portion 22 to pass through. The blue filter portion covers the corresponding third light-emitting portion 23 and allows blue light in the white light emitted by the third light-emitting portion 23. As a result, the full-color display is achieved through the lights of three primary colors exiting from the plurality of filter portions and the white light emitted by the fourth light-emitting portion 24.

As for the display panel described above, it is found by the researchers that full-color display has a poor effect when achieving the full-color display. It is found through careful study that for the first sub-pixel formed by the first light-emitting portion 21 and the corresponding red filter portion, the second sub-pixel formed by the second light-emitting portion 22 and the corresponding green filter portion, the third sub-pixel formed by the third light-emitting portion 23 and the corresponding blue filter portion, and the fourth sub-pixel formed by the fourth light-emitting portion 24, since the light-emitting portions included in the first sub-pixel, the second sub-pixel, the third sub-pixel and the fourth sub-pixel have the same reflectivity, and the fourth sub-pixel does not include a filter portion, a light-emitting effect of the fourth sub-pixel is better than light-emitting effects of the first sub-pixel, the second sub-pixel and the third sub-pixel. Therefore, the light-emitting effect of the fourth sub-pixel deviates from a target light color while ensuring the light-emitting effects of the first sub-pixel, the second sub-pixel and the third sub-pixel, or the light-emitting effects of the first sub-pixel, the second sub-pixel and the third sub-pixel deviate from target light colors while ensuring the light-emitting effect of the fourth sub-pixel, thereby affecting the display effect of the display panel.

Specifically, as shown in FIG. 2, the light-emitting portion includes an anode 211, a light-emitting functional layer 212, a cathode 213, and a pixel definition layer 214 located between the anode 211 and the light-emitting functional layer 212 and having pixel openings. Taking a top-emission light-emitting portion as an example, as shown in FIG. 2, a sub-pixel (taking the sub-pixel corresponding to the first light-emitting portion 21 as an example) may be divided into three reflective regions. The three reflective regions include an anode light-emitting reflective region AA (a region surrounded by the pixel opening), an anode edge reflective region BB (a region between an edge of the pixel opening and an edge of the light-shielding layer 4) and a light-shielding reflective region CC (a region where the light-shielding layer 4 is located).

In this case, the reflectivity of the first sub-pixel in the anode light-emitting reflective region AA is R_{red-sim}, the reflectivity of the second sub-pixel in the anode light-emitting reflective region AA is R_{green-sim}, the reflectivity of the third sub-pixel in the anode light-emitting reflective region AA is R_{blue-sim}, and the reflectivity of the fourth sub-pixel in the anode light-emitting reflective region AA is R_{w-sim}. The reflectivity of the first sub-pixel in the anode edge reflective region BB, the reflectivity of the second sub-pixel in the anode edge reflective region BB, the reflectivity of the third sub-pixel in the anode edge reflective region BB, and the reflectivity of the fourth sub-pixel in the anode edge reflective region BB are all R_{PDL-sim}. The reflectivity of the first sub-pixel in the light-shielding reflective region CC, the reflectivity of the second sub-pixel in the light-shielding reflective region CC, the reflectivity of the third sub-pixel in the light-shielding reflective region CC, and the reflectivity of the fourth sub-pixel in the light-shielding reflective region CC is R_{bm-sim}. In addition, the transmittance of the first sub-pixel is T_{redCF}, the transmittance of the second sub-pixel is T_{greenCF}, and the transmittance of the third sub-pixel is T_{blueCF}. The pixel aperture ratios of the first sub-pixel, the second sub-pixel, the third sub-pixel and the fourth sub-pixel in the anode light-emitting reflective region AA are all S_{rgbw}. The area ratios of gap portions of the first sub-pixel, the second sub-pixel, the third sub-pixel and the fourth sub-pixel in the anode edge reflective region BB are all S_{PDL}. The area ratios of the light-shielding layer of the first sub-pixel, the second sub-pixel, the third sub-pixel and the fourth sub-pixel in the light-shielding reflective region CC are all S_{bm}.

Furthermore, for a pixel including the first sub-pixel, the second sub-pixel, the third sub-pixel and the fourth sub-pixel, the pixel reflectivity of the first sub-pixel is approximately expressed as P_{red}=R_{red-sim}×T_{redCF}×T_{redCF}×S_{rgbw}; the pixel reflectivity of the second sub-pixel is approximately expressed as R_{green}=R_{green-sim}×T_{greenCF}×T_{greenCF}×S_{rgbw}; the pixel reflectivity of the third sub-pixel is approximately expressed as R_{blue}=R_{blue-sim}×T_{blueCF}×T_{blueCF}×S_{rgbw}; and the pixel reflectivity of the fourth sub-pixel is approximately expressed as R_{w}=R_{w-sim}×S_{rgbw}. The total reflectivity of the anode edge reflective region BB is approximately expressed as R_{PDL}=R_{PDL-sim}×T_{redCF}×T_{redCF}×S_{PDL}+R_{PDL-sim}×T_{greenCF}×T_{greenCF}×S_{PDL}+R_{PDL-sim}×T_{blueCF}×T_{blueCF}×S_{PDL}+R_{PDL-sim}×S_{PDL}. The total reflectivity of the light-shielding reflective region CC is approximately expressed as R_{bm}=R_{bm-sim}×S_{bm}×4.

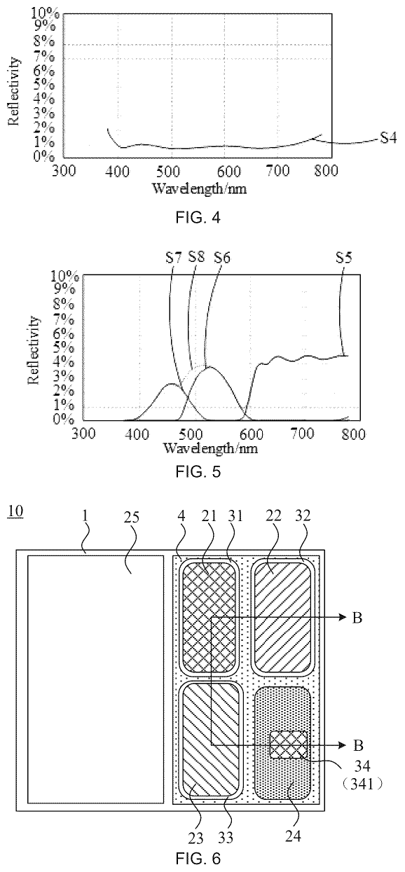

Here, by considering an example where a wavelength of the light exit from the first sub-pixel is greater than a wavelength of the light exit from the second sub-pixel, and the wavelength of the light exit from the second sub-pixel is greater than a wavelength of the light exit from the third sub-pixel (a wavelength of the light exit from the first sub-pixel>a wavelength of the light exit from the second sub-pixel>a wavelength of the light exit from the third sub-pixel), the first sub-pixel emits red light, the second sub-pixel emits green light, and the third sub-pixel emits blue light. In this case, FIG. 3 shows a curve S1 of the pixel reflectivity of the first sub-pixel in the anode light-emitting reflective region AA, a curve S2 of the pixel reflectivity of the second sub-pixel in the anode light-emitting reflective region AA, and a curve S3 of the pixel reflectivity of the third sub-pixel in the anode light-emitting reflective region AA. FIG. 4 shows a curve S4 of the total reflectivity of the light-shielding reflective region CC. FIG. 5 shows the reflectivity S5 of the first sub-pixel in the anode edge reflective region BB, the reflectivity S6 of the second sub-pixel in the anode edge reflective region BB, the reflectivity S7 of the fourth sub-pixel in the anode edge reflective region BB, and the reflectivity S8 of the third sub-pixel in the anode edge reflective region BB.

It can be seen that the pixel reflectivity of the fourth sub-pixel is much greater than the pixel reflectivity of the first sub-pixel, the pixel reflectivity of the second sub-pixel and the pixel reflectivity of the third sub-pixel. The pixel reflectivity of the first sub-pixel, the second sub-pixel and the third sub-pixel is approximately equal to the total reflectivity of the anode edge reflective region BB, and the total reflectivity of the anode edge reflective region BB is greater than the total reflectivity of the light-shielding reflective region CC. Therefore, the light-emitting effect of the fourth sub-pixel deviates from a target light color while ensuring the light-emitting effects of the first sub-pixel, the second sub-pixel and the third sub-pixel, or the light-emitting effects of the first sub-pixel, the second sub-pixel and the third sub-pixel deviate from target light colors while ensuring the light-emitting effect of the fourth sub-pixel, thereby affecting the display effect of the display panel.

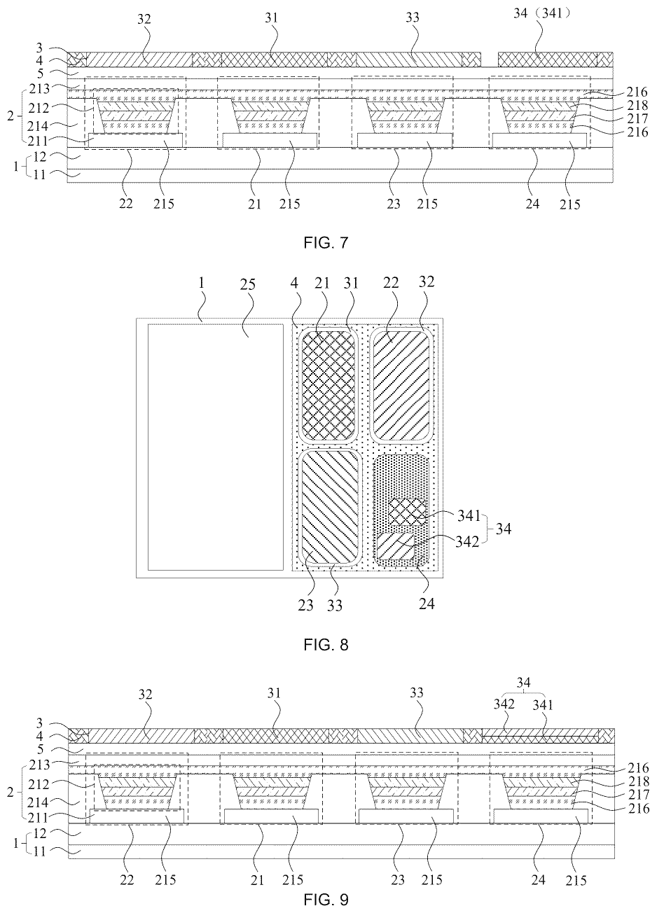

In light of this, embodiments of the present disclosure provide a display panel. As shown in FIGS. 6 and 7, the display panel 10 includes a light-emitting layer 2 and a filter layer 3. The filter layer 3 is located on a light-exit side of the light-emitting layer 2. The light-emitting layer 2 includes a plurality of light-emitting portions distributed in an array, and the plurality of light-emitting portions include at least a light-emitting portion for emitting white light. The filter layer 3 includes a plurality of filter portions corresponding one-to-one to the plurality of light-emitting portions. The plurality of filter portions include a first filter portion 31, a second filter portion 32, a third filter portion 33 and a fourth filter portion 34, and a light-emitting portion corresponding to the fourth filter portion 34 emits the white light. In a direction perpendicular to the display panel, the first filter portion 31, the second filter portion 32 and the third filter portion 33 all cover the corresponding light-emitting portions, and the fourth filter portion 34 at least partially overlaps with the corresponding light-emitting portion. The first filter portion 31 is configured to allow a first color light to exit, the second filter portion 32 is configured to allow a second color light to exit, the third filter portion 33 is configured to allow a third color light to exit, and the fourth filter portion 34 is configured to allow white light to exit.

The plurality of light-emitting portions include a first light-emitting portion 21 corresponding to the first filter portion 31, a second light-emitting portion 22 corresponding to the second filter portion 32, a third light-emitting portion 23 corresponding to the third filter portion 33, and a fourth light-emitting portion 24 (for emitting white light) corresponding to the fourth filter portion 34. The first light-emitting portion 21 and the corresponding first filter portion 31 form a first sub-pixel, the second light-emitting portion 22 and the corresponding second filter portion 32 form a second sub-pixel, the third light-emitting portion 23 and the corresponding third filter portion 33 form a third sub-pixel, and the fourth light-emitting portion 24 and the corresponding fourth filter portion 34 form a fourth sub-pixel.

In this way, in the display panel provided by the embodiments of the present disclosure, the first color light exits from the first sub-pixel, the second color light exits from the second sub-pixel, the third color light exits from the third sub-pixel, and the white light exits from the fourth sub-pixel. Thus, the display panel may achieve the full-color display. In addition, the provision of the fourth filter portion 34 may reduce the pixel reflectivity of the fourth sub-pixel. Thus, the pixel reflectivity of the fourth sub-pixel is close to the pixel reflectivity of the first sub-pixel, the pixel reflectivity of the second sub-pixel and the pixel reflectivity of the third sub-pixel. That is, the light-emitting effects of the first sub-pixel, the second sub-pixel, the third sub-pixel and the fourth sub-pixel are made close, thereby ensuring the display effect of the display panel.

In the embodiments of the present disclosure, the light-emitting layer 2 includes a plurality of light-emitting units distributed in an array, and each light-emitting unit includes a first light-emitting portion 21, a second light-emitting portion 22, a third light-emitting portion 23 and a fourth light-emitting portion 24, so as to achieve full-color lighting of each light-emitting unit.

As shown in FIG. 7, the light-emitting portion includes an anode 211, a light-emitting functional layer 212, a cathode 213, and a pixel definition layer 214 located between the anode 211 and the light-emitting functional layer 212.

For a top-emission light-emitting portion, the cathode 213 may be a transparent film layer (a transparent cathode 213), and the anode 211 may be a reflective film layer (i.e., a reflective anode 215 shown in FIG. 7), so that the light emitted by the light-emitting functional layer 212 can pass through the cathode 213 under the reflection effect of the anode 211. For a bottom-emission light-emitting portion, the cathode 213 may be a reflective film layer (a reflective cathode 213), and the anode 211 may be a transparent film layer (a transparent anode 211), so that the light emitted by the light-emitting functional layer 212 can pass through the anode 211 under the reflection effect of the cathode 213.

Taking the light-emitting functional layer 212 emitting white light as an example, the light-emitting functional layer 212 may have a film layer structure in which a red functional layer 217, a green functional layer and a blue functional layer 216 are stacked in sequence, alternatively, the light-emitting functional layer 212 may have a film layer structure in which a blue functional layer 216, a red functional layer 217, a yellow functional layer 218 and a blue functional layer 216 are stacked in sequence as shown in FIG. 7. Of course, the light-emitting functional layer 212 may also have other film layer structures, which is not limited in the embodiments of the present disclosure.

Optionally, as shown in FIG. 6, the display panel further includes a light-transmitting region 25 located between two adjacent light-emitting units. The setting of the light-transmitting region 25 may achieve light-transmitting performance of the display panel while achieving the full-color display of the display panel.

In the embodiments of the present disclosure, as shown in FIG. 6 or 7, the display panel further includes a light-shielding layer 4. The light-shielding layer 4 is located in the same layer as the filter layer 3. The light-shielding layer 4 is distributed between two adjacent filter portions to separate the plurality of filter portions, thereby preventing cross-color between different filter portions and avoiding affecting the display effect.

In the embodiments of the present disclosure, as shown in FIG. 7, the display panel further includes a base substrate 1, and the base substrate 1 is located on a side of the light-emitting layer 2 proximate to the anode 211. In combination with the above-mentioned case where the light-emitting portion has a bottom-emission mode, the base substrate 1 may be a transparent substrate, so as to ensure transmission of the light.

The base substrate 1 may be a driving substrate (i.e., a silicon substrate integrated with a driving circuit). Alternatively, as shown in FIG. 7, the base substrate 1 may include a substrate 11 and a driving layer 12 located on a side of the substrate 11 proximate to the light-emitting layer 2.

A material of the substrate 11 may be an inorganic material or an organic material. For example, in some implementations, the material of the substrate 11 may be a glass material such as soda-lime glass, quartz glass or sapphire glass, or a metal material such as stainless steel, aluminum or nickel. In some other implementations, the material of the substrate 11 may be polymethyl methacrylate (PMMA), polyvinyl alcohol (PVA), polyvinyl phenol (PVP), polyether sulfone (PES), polyimide, polyamide, polyacetal, polycarbonate (PC), polyethylene terephthalate (PET), polyethylene naphthalate (PEN), or a combination thereof.

Optionally, the substrate 11 may be a composite of multiple layers of materials in addition to a single layer of material. For example, in some implementations, the substrate 11 includes a bottom film layer, a pressure-sensitive adhesive layer, a first polyimide layer and a second polyimide layer that are sequentially stacked.

The driving layer 12 includes a plurality of driving circuits, and a driving circuit is electrically connected to a light-emitting portion of the light-emitting layer 2, so as to ensure normal light emission of the light-emitting portion. The driving circuit may include a plurality of transistors and capacitor(s).

The transistors may be thin film transistors, and the thin film transistors may be selected from top-gate thin film transistors, bottom-gate thin film transistors or dual-gate thin film transistors. The capacitor may be a capacitor with dual electrode plates or a capacitor with three electrode plates. A material of a control electrode of the thin film transistor may be an amorphous silicon semiconductor material, a low-temperature polysilicon semiconductor material, a metal-oxide-semiconductor material, an organic semiconductor material or other types of semiconductor materials. The thin film transistor may be an N-type thin film transistor or a P-type thin film transistor.

It can be understood that among the plurality of transistors included in the driving circuit, any two transistors may have the same or different types. For example, in some implementations, in a driving circuit, some of the transistors are N-type transistors, and the rest of the transistors are P-type transistors. As another example, in some other implementations, in a driving circuit, materials of control electrodes of some transistors may be low-temperature polysilicon semiconductor materials, and materials of active layers of some transistors may be metal-oxide-semiconductor materials.

The driving layer 12 includes an insulating buffer layer, a transistor layer, an interlayer dielectric layer, a source-drain metal layer and a planarization layer that are arranged in sequence in a direction away from the substrate 11. The transistor layer includes a semiconductor layer, a gate insulating layer and a gate metal layer that are stacked between the substrate 11 and the interlayer dielectric layer. The positional relationship of all film layers included in the transistor layer may be determined based on the type (top-gate, bottom-gate or duel-gate) of the thin film transistor. For example, the transistor layer includes a semiconductor layer, a gate insulating layer and a gate metal layer that are stacked in sequence in a direction away from the substrate 11, and the thin film transistor formed in this case is a top-gate thin film transistor. Alternatively, the transistor layer includes a gate metal layer, a gate insulating layer and a semiconductor layer that are stacked in sequence in a direction away from the substrate 11, and the thin film transistor formed in this case is a bottom-gate thin film transistor.

In some embodiments, a material of the insulating buffer layer may be an inorganic insulating material such as silicon oxide or silicon nitride. The insulating buffer layer may be a single inorganic material layer or a plurality of stacked inorganic material layers. The semiconductor layer may be used to form an active portion (control electrode) of each transistor included in the driving circuit, and each active portion includes a channel region and two connecting portions (i.e., source and drain) located on both sides of the channel region. The semiconductor layer may be a single semiconductor layer or two semiconductor layers. The gate metal layer may be used to form scan lines and other gate metal layer wirings, and may also be used to form a second electrode plate of a capacitor. The gate metal layer may be a single gate metal layer, or two or three gate metal layers. The source-drain metal layer may be used to form power lines, data lines, sensing lines, connecting lines and other source-drain metal layer wirings, and may also be used to form a first electrode plate of the capacitor. The planarization layer is provided with a plurality of first via holes therein, and an anode 211 of a light-emitting portion is connected to a driving circuit through a first via hole.

It can be understood that in a case where the gate metal layer or the semiconductor layer has a multi-layer structure, the number of the gate insulating layer(s) in the transistor layer may be adaptively increased or decreased. For example, in some implementations, the transistor layer includes a low-temperature polysilicon semiconductor layer, a gate insulating layer, a metal oxide semiconductor layer, another gate insulating layer and a gate metal layer that are sequentially stacked on the substrate 11.

Optionally, the driving layer 12 further includes a passivation layer disposed between the source-drain metal layer and the planarization layer, so as to protect the source-drain metal layer through the provision of the passivation layer.

In some embodiments, the display panel may further include a thin film encapsulation layer 5. The thin film encapsulation layer 5 is disposed on a side of the filter layer 3 proximate to the light-emitting layer 2, or may also be disposed on a side of the filter layer 3 away from the light-emitting layer 2. The thin film encapsulation layer 5 may include inorganic encapsulation layers and an organic encapsulation layer that are disposed alternately. The inorganic encapsulation layer may effectively block external moisture and oxygen, thereby preventing material degradation caused by invasion of moisture and oxygen into the light-emitting functional layer 212 of the light-emitting portion. The organic encapsulation layer is located between two adjacent inorganic encapsulation layers, so as to achieve planarization and reduce stress between the inorganic encapsulation layers.

The display panel has a display region and a peripheral region located at a periphery of the display region. An edge of the inorganic encapsulation layer may be located in the peripheral region, and an edge of the organic encapsulation layer may be located between an edge of the display region and the edge of the inorganic encapsulation layer. For example, the thin film encapsulation layer 5 includes a first inorganic encapsulation layer, an organic encapsulation layer and a second inorganic encapsulation layer that are sequentially stacked on a side of the light-emitting layer 2 away from the substrate 11.

In some embodiments, the display panel may further include a touch function layer, and the touch function layer is disposed on a side of the thin film encapsulation layer 5 away from the substrate 11 and used for implementing touch operation of the display panel.

In the embodiments of the present disclosure, for the first filter portion 31, the second filter portion 32 and the third filter portion 33 included in the plurality of filter portions, optionally, the first filter portion 31 is one of a red filter portion, a green filter portion and a blue filter portion, the second filter portion 32 is another one of the red filter portion, the green filter portion and the blue filter portion, and the third filter portion 33 is the remaining one of the red filter portion, the green filter portion and the blue filter portion.

For example, the first filter portion 31 is a red filter portion, and the first sub-pixel is a red sub-pixel; the second filter portion 32 is a green filter portion, and the second sub-pixel is a green sub-pixel; the third filter portion 33 is a blue filter portion, and the third sub-pixel is a blue sub-pixel. Of course, the first filter 31, the second filter 32 and the third filter 33 may also be filter portions of other colors. For details, reference may be made to the relevant technologies, as long as the full-color display of the display panel can be achieved in combination with the fourth filter portion 34. For example, the first filter portion 31 is a green filter portion, and the first sub-pixel is a green sub-pixel; the second filter portion 32 is a red filter portion, and the second sub-pixel is a red sub-pixel; the third filter portion 33 is a blue filter portion, and the third sub-pixel is a blue sub-pixel.

In the embodiments of the present disclosure, for the fourth filter portion 34, the setting type of the fourth filter portion 34 may be determined by comparing a pre-detected spectrum of white light exit from the fourth sub-pixel with a normalized spectrum of a reference white point.

In some embodiments, it can be found after comparing the spectrum of the white light exit from the fourth sub-pixel with the normalized spectrum of the reference white point that, the white light exit from the fourth sub-pixel contains insufficient light of a single color. In this case, as shown in FIG. 6 or 7, the fourth filter portion 34 may be set as a single-color filter portion. Furthermore, the fourth filter portion 34 may be disposed in the same layer as one of the first filter portion 31, the second filter portion 32 and the third filter portion 33 with the same green light color.

The explanation is made in detail in combination with the above example where the first filter portion 31 is a red filter portion, the second filter portion 32 is a green filter portion, and the third filter portion 33 is a blue filter portion.

For example, it can be found after comparing the spectrum of the white light exit from the fourth sub-pixel with the normalized spectrum of the reference white point that, in the white light exit from the fourth sub-pixel, a red band is lower than a green band and a blue band, resulting in insufficient red light, which lead to be overall bluish-green of the white light exit from the fourth sub-pixel. In combination with the above-mentioned case where the first filter portion 31 is a red filter portion, the fourth filter portion 34 may be set to include a second filter sub-portion 342, and the light exit from the second filter sub-portion 342 has the same color as the light exit from the first filter portion 31. Thus, the provision of the second filter sub-portion 342 may enhance the red light band in the white light, so as to ensure sufficient red light, thereby ensuring that the spectrum of the white light after passing through the second filter sub-portion 342 approximately coincides with the normalized spectrum of the reference white point.

Optionally, the second filter sub-portion 342 included in the fourth filter portion 34 may be provided in the same layer and made of the same material as the first filter portion 31. In this way, a manufacturing process of the second filter sub-portion 342 may be simplified.

For example, it can be found after comparing the spectrum of the white light exit from the fourth sub-pixel with the normalized spectrum of the reference white point that, in the white light exit from the fourth sub-pixel, a green band is lower than a red band and a blue band, resulting in insufficient green light, which lead to be overall purplish of the white light exit from the fourth sub-pixel. In combination with the above-mentioned case where the second filter portion 32 is a green filter portion, the fourth filter portion 34 may be set to include a first filter sub-portion 341, and the light exit from the first filter sub-portion 341 has the same color as the light exit from the second filter portion 32. Thus, the provision of the first filter sub-portion 341 may enhance the green light band in the white light, so as to ensure sufficient green light, thereby ensuring that the spectrum of the white light after passing through the first filter sub-portion 341 approximately coincides with the normalized spectrum of the reference white point.

Optionally, the first filter sub-portion 341 included in the fourth filter portion 34 may be provided in the same layer and made of the same material as the second filter portion 32. In this way, a manufacturing process of the first filter sub-portion 341 may be simplified.

For example, it can be found after comparing the spectrum of the white light exit from the fourth sub-pixel with the normalized spectrum of the reference white point that, in the white light exit from the fourth sub-pixel, a blue band is lower than a red band and a green band, resulting in insufficient blue light, which lead to be overall yellowish of the white light exit from the fourth sub-pixel. In combination with the above-mentioned case where the third filter portion 33 is a blue filter portion, the fourth filter portion 34 may be set to include a fourth filter sub-portion 343, and the light exit from the fourth filter sub-portion 343 has the same color as the light exit from the third filter portion 33. Thus, the provision of the fourth filter sub-portion 343 may enhance the blue light band in the white light, so as to ensure sufficient blue light, thereby ensuring that the spectrum of the white light after passing through the fourth filter sub-portion 343 approximately coincides with the normalized spectrum of the reference white point.

Optionally, the fourth filter sub-portion 343 included in the fourth filter portion 34 may be provided in the same layer and made of the same material as the third filter portion 33. In this way, a manufacturing process of the fourth filter sub-portion 343 may be simplified.

An area and a thickness of the fourth filter portion 34 determine a light-filtering effect of the fourth filter portion 34 on the white light emitted by the fourth light-emitting portion 24. To ensure that the spectrum of the white light filtered by the fourth filter portion 34 is close to the normalized spectrum of the reference white point, continuing with the example of the overall purplish of the white light exit from the fourth sub-pixel, a correspondence table of area ratios and thickness ratios may be pre-set. Then, based on a ratio of an area of the fourth filter portion 34 (first filter sub-portion 341) to an area of a light-emitting region of the corresponding fourth light-emitting portion 24, a thickness of the first filter sub-portion 341 may be determined in combination with a thickness of the second filter portion 32, so as to ensure that the spectrum of the white light filtered by the first filter sub-portion 341 approximately coincides with the normalized spectrum of the reference white point.

Here, the area of the first filter sub-portion 341 refers to an area of a region enclosed by an edge of the first filter sub-portion 341, that is, an area of an orthographic projection of the first filter sub-portion 341 on the base substrate 1. The area of the light-emitting region of the fourth light-emitting portion 24 refers to an area of a region enclosed by the pixel opening of the fourth light-emitting portion 24.

For example, in a case where a ratio of an area of the first filter sub-portion 341 to an area of a light-emitting region of the fourth light-emitting portion 24 is greater than or equal to a reference value, a thickness of the first filter sub-portion 341 is set to be less than a thickness of the second filter portion 32. In a case where the ratio of the area of the first filter sub-portion 341 to the area of the light-emitting region of the fourth light-emitting portion 24 is less than the reference value, the thickness of the first filter sub-portion 341 is set to be greater than or equal to the thickness of the second filter portion 32.

The reference value may be greater than or equal to 30% and less than or equal to 60%. For example, the reference value is 30%, 40%, 50% or 60%. For example, in a case where the ratio of the area of the first filter sub-portion 341 to the area of the light-emitting region of the fourth light-emitting portion 24 is greater than or equal to 40%, the thickness of the first filter sub-portion 341 is set to be less than the thickness of the second filter portion 32. In a case where the ratio of the area of the first filter sub-portion 341 to the area of the light-emitting region of the fourth light-emitting portion 24 is less than 40%, the thickness of the first filter sub-portion 341 is set to be greater than or equal to the thickness of the second filter portion 32.

For example, in a case where the ratio of the area of the first filter sub-portion 341 to the area of the light-emitting region of the fourth light-emitting portion 24 is greater than or equal to a first reference value, the thickness of the first filter sub-portion 341 is set to be less than ½ of the thickness of the second filter portion 32. In a case where the ratio of the area of the first filter sub-portion 341 to the area of the light-emitting region of the fourth light-emitting portion 24 is less than the first reference value and greater than or equal to a second reference value, the thickness of the first filter sub-portion 341 is set to be greater than or equal to ½ of the thickness of the second filter portion 32 and less than or equal to ⅔ of the thickness of the second filter portion 32. In a case where the ratio of the area of the first filter sub-portion 341 to the area of the light-emitting region of the fourth light-emitting portion 24 is less than the second reference value, the thickness of the first filter sub-portion 341 is set to be greater than ⅔ of the thickness of the second filter portion 32 and less than or equal to twice the thickness of the second filter portion 32.

The first reference value may be greater than or equal to 60% and less than or equal to 80%, and the second reference value may be greater than or equal to 20% and less than or equal to 40%. For example, the first reference value is 60%, 70% or 80%, and the second reference value is 20%, 30% or 40%. For example, in a case where the ratio of the area of the first filter sub-portion 341 to the area of the light-emitting region of the fourth light-emitting portion 24 is greater than or equal to 70%, the thickness of the first filter sub-portion 341 is set to be less than ½ of the thickness of the second filter portion 32. In a case where the ratio of the area of the first filter sub-portion 341 to the area of the light-emitting region of the fourth light-emitting portion 24 is less than 70% and greater than or equal to 30%, the thickness of the first filter sub-portion 341 is set to be greater than or equal to ½ of the thickness of the second filter portion 32 and less than or equal to ⅔ of the thickness of the second filter portion 32. In a case where the ratio of the area of the first filter sub-portion 341 to the area of the light-emitting region of the fourth light-emitting portion 24 is less than 30%, the thickness of the first filter sub-portion 341 is set to be greater than ⅔ of the thickness of the second filter portion 32 and less than or equal to twice the thickness of the second filter portion 32.

In some other embodiments, it can be found after comparing the spectrum of the white light exit from the fourth sub-pixel with the normalized spectrum of the reference white point that, the white light exit from the fourth sub-pixel contains insufficient light of two colors. In this case, as shown in FIG. 8 or 9, the fourth filter portion 34 may be set to include two filter sub-portions with different colors, or the fourth filter portion 34 may be set as a third filter sub-portion that is a synthesis of two colors.

For a case where the fourth filter portion 34 includes two filter sub-portions with different colors, that is, the fourth filter portion 34 further includes a second filter sub-portion 342 in addition to the first filter sub-portion 341, the light exit from the second filter sub-portion 342 has the same color as the light exit from the first filter portion 31.

The first filter sub-portion 341 and the second filter sub-portion 342 may be arranged in the same layer as shown in FIG. 8, or may be arranged in stacked layers as shown in FIG. 9.

For the insufficient light of two colors in the white light exit from the fourth sub-pixel, if a light band of light of one color is lower than a light band of light of the other color, an area and/or a thickness of a filter sub-portion corresponding to the light of one color may be set to be less than an area and/or a thickness of a filter sub-portion corresponding to the light of the other color, so as to ensure that the spectrum of the white light exit from the fourth sub-pixel approximately coincides with the normalized spectrum of the reference white point.

The explanation is made in detail in combination with the above example where the first filter portion 31 is a red filter portion, the second filter portion 32 is a green filter portion, and the third filter portion 33 is a blue filter portion.

For example, it can be found after comparing the spectrum of the white light exit from the fourth sub-pixel with the normalized spectrum of the reference white point that, in the white light exit from the fourth sub-pixel, a red band and a green band are lower than a blue band, resulting in insufficient red light and green light, which lead to be overall bluish of the white light exit from the fourth sub-pixel. In this case, the fourth filter portion 34 may be set to include a first filter sub-portion 341 and a second filter sub-portion 342, the light exit from the first filter sub-portion 341 has the same color as the light exit from the second filter portion 32, and the light exit from the second filter sub-portion 342 has the same color as the light exit from the first filter portion 31. Thus, the provision of the first filter sub-portion 341 and the second filter sub-portion 342 may enhance the red light band and the green light band in the white light, so as to ensure sufficient red light and green light, thereby ensuring that the spectrum of the white light after passing through the first filter sub-portion 341 and the second filter sub-portion 342 approximately coincides with the normalized spectrum of the reference white point.

Optionally, the first filter sub-portion 341 included in the fourth filter portion 34 may be provided in the same layer and made of the same material as the second filter portion 32, and the second filter sub-portion 342 included in the fourth filter portion 34 may be provided in the same layer and made of the same material as the first filter portion 31. In this way, manufacturing processes of the first filter sub-portion 341 and the second filter sub-portion 342 may be simplified.

If the red light band is lower than the green light band, an area and/or a thickness of the second filter sub-portion 342 may be set to be less than an area and/or a thickness of the first filter sub-portion 341. If the red light band is higher than the green light band, the area and/or the thickness of the second filter sub-portion 342 may be set to be greater than the area and/or the thickness of the first filter sub-portion 341.

For example, it can be found after comparing the spectrum of the white light exit from the fourth sub-pixel with the normalized spectrum of the reference white point that, in the white light exit from the fourth sub-pixel, a red band and a blue band are lower than a green band, resulting in insufficient red light and blue light, which lead to be overall greenish of the white light exit from the fourth sub-pixel. In this case, the fourth filter portion 34 may be set to include a second filter sub-portion 342 and a fourth filter sub-portion 343, the light exit from the second filter sub-portion 342 has the same color as the light exit from the first filter portion 31, and the light exit from the fourth filter sub-portion 343 has the same color as the light exit from the third filter portion 33. Thus, the provision of the second filter sub-portion 342 and the fourth filter sub-portion 343 may enhance the red light band and the blue light band in the white light, so as to ensure sufficient red light and blue light, thereby ensuring that the spectrum of the white light after passing through the second filter sub-portion 342 and the fourth filter sub-portion 343 approximately coincides with the normalized spectrum of the reference white point.

Optionally, the second filter sub-portion 342 included in the fourth filter portion 34 may be provided in the same layer and made of the same material as the first filter portion 31, and the fourth filter sub-portion 343 included in the fourth filter portion 34 may be provided in the same layer and made of the same material as the third filter portion 33. In this way, manufacturing processes of the second filter sub-portion 342 and the fourth filter sub-portion 343 may be simplified.

If the red light band is lower than the blue light band, an area and/or a thickness of the second filter sub-portion 342 may be set to be less than an area and/or a thickness of the fourth filter sub-portion 343. If the red light band is higher than the blue light band, the area and/or the thickness of the second filter sub-portion 342 may be set to be greater than the area and/or the thickness of the fourth filter sub-portion 343.

For example, it can be found after comparing the spectrum of the white light exit from the fourth sub-pixel with the normalized spectrum of the reference white point that, in the white light exit from the fourth sub-pixel, a green band and a blue band are lower than a red band, resulting in insufficient green light and blue light, which lead to be overall reddish of the white light exit from the fourth sub-pixel. In this case, the fourth filter portion 34 may be set to include a first filter sub-portion 341 and a fourth filter sub-portion 343, the light exit from the first filter sub-portion 341 has the same color as the light exit from the second filter portion 32, and the light exit from the fourth filter sub-portion 343 has the same color as the light exit from the third filter portion 33. Thus, the provision of the first filter sub-portion 341 and the fourth filter sub-portion 343 may enhance the green light band and the blue light band in the white light, so as to ensure sufficient green light and blue light, thereby ensuring that the spectrum of the white light after passing through the first filter sub-portion 341 and the fourth filter sub-portion 343 approximately coincides with the normalized spectrum of the reference white point.

Optionally, the first filter sub-portion 341 included in the fourth filter portion 34 may be provided in the same layer and made of the same material as the second filter portion 32, and the fourth filter sub-portion 343 included in the fourth filter portion 34 may be provided in the same layer and made of the same material as the third filter portion 33. In this way, manufacturing processes of the first filter sub-portion 341 and the fourth filter sub-portion 343 may be simplified

If the green light band is lower than the blue light band, an area and/or a thickness of the first filter sub-portion 341 may be set to be less than an area and/or a thickness of the fourth filter sub-portion 343. If the green light band is higher than the blue light band, the area and/or the thickness of the first filter sub-portion 341 may be set to be greater than the area and/or the thickness of the fourth filter sub-portion 343.

For a case where the fourth filter portion 34 includes the third filter sub-portion, the light exit from the third filter sub-portion has the same color as the mixed light of the light exit from the first filter portion 31 and the light exit from the second filter portion 32.

The area and the thickness of the third filter sub-portion determine a light-filtering effect on the colored light in the white light emitted by the fourth light-emitting portion 24. To ensure that the spectrum of the white light filtered by the third filter sub-portion is close to the normalized spectrum of the reference white point, continuing with the example of the overall bluish of the white light exit from the fourth sub-pixel, a correspondence table of area ratios and thickness ratios may be pre-set. Then, based on a ratio of an area of the third filter sub-portion to an area of a light-emitting region of the corresponding fourth light-emitting portion 24, a thickness of the third filter sub-portion may be determined in combination with a thickness of the first filter portion 31 and a thickness of the second filter portion 32, so as to ensure that the spectrum of the white light filtered by the third filter sub-portion approximately coincides with the normalized spectrum of the reference white point.

For example, in a case where a ratio of an area of the third filter sub-portion to an area of a light-emitting region of the fourth light-emitting portion 24 is greater than or equal to a reference value, a thickness of the third filter sub-portion is set to be less than a thickness of the first filter portion 31 and less than a thickness of the second filter portion 32. In a case where the ratio of the area of the third filter sub-portion to the area of the light-emitting region of the fourth light-emitting portion 24 is less than the reference value, the thickness of the third filter sub-portion is set to be greater than or equal to the thickness of the first filter portion 31 and greater than or equal to the thickness of the second filter portion 32.

The reference value may refer to the above-mentioned embodiments. For example, in a case where the ratio of the area of the third filter sub-portion to the area of the light-emitting region of the fourth light-emitting portion 24 is greater than or equal to 40%, the thickness of the third filter sub-portion is set to be less than the thickness of the first filter portion 31 and less than the thickness of the second filter portion 32. In a case where the ratio of the area of the third filter sub-portion to the area of the light-emitting region of the fourth light-emitting portion 24 is less than 40%, the thickness of the third filter sub-portion is set to be greater than or equal to the thickness of the first filter portion 31 and greater than or equal to the thickness of the second filter portion 32.

For example, in a case where the ratio of the area of the third filter sub-portion to the area of the light-emitting region of the fourth light-emitting portion 24 is greater than or equal to a first reference value, the thickness of the third filter sub-portion is set to be less than ½ of the thickness of the first filter portion 31 and less than ½ of the thickness of the second filter portion 32. In a case where the ratio of the area of the third filter sub-portion to the area of the light-emitting region of the fourth light-emitting portion is less than the first reference value and greater than or equal to a second reference value, the thickness of the third filter sub-portion is set to be greater than or equal to ½ of the thickness of the first filter portion 31 and less than or equal to ⅔ of the thickness of the first filter portion 31, and greater than or equal to ½ of the thickness of the second filter portion 32 and less than or equal to ⅔ of the thickness of the second filter portion 32. In a case where the ratio of the area of the third filter sub-portion to the area of the light-emitting region of the fourth light-emitting portion 24 is less than the second reference value, the thickness of the third filter sub-portion is set to be greater than ⅔ of the thickness of the first filter portion 31 and less than or equal to twice the thickness of the first filter portion 31, and greater than ⅔ of the thickness of the second filter portion 32 and less than or equal to twice the thickness of the second filter portion 32.

The first reference value and the second reference value may refer to the above-mentioned embodiments. For example, in a case where the ratio of the area of the third filter sub-portion to the area of the light-emitting region of the fourth light-emitting portion 24 is greater than or equal to 60%, the thickness of the third filter sub-portion is set to be less than ½ of the thickness of the first filter portion 31 and less than ½ of the thickness of the second filter portion 32. In a case where the ratio of the area of the third filter sub-portion to the area of the light-emitting region of the fourth light-emitting portion 24 is less than 60% and greater than or equal to 30%, the thickness of the third filter sub-portion is set to be greater than or equal to ½ of the thickness of the first filter portion 31 and less than or equal to ⅔ of the thickness of the first filter portion 31, and greater than or equal to ½ of the thickness of the second filter portion 32 and less than or equal to ⅔ of the thickness of the second filter portion 32. In a case where the ratio of the area of the third filter sub-portion to the area of the light-emitting region of the fourth light-emitting portion 24 is less than 30%, the thickness of the third filter sub-portion is set to be greater than ⅔ of the thickness of the first filter portion 31 and less than or equal to twice the thickness of the first filter portion 31, and greater than ⅔ of the thickness of the second filter portion 32 and less than or equal to twice the thickness of the second filter portion 32.

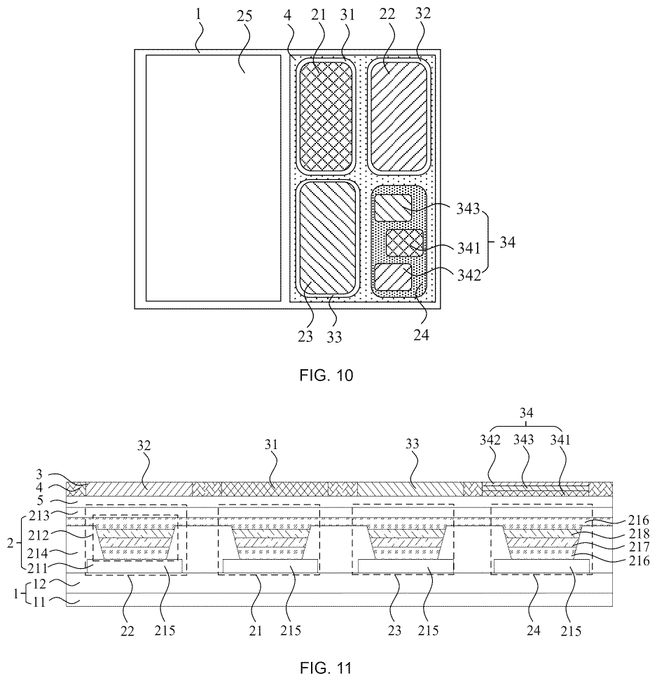

In some other embodiments, it can be found after comparing the spectrum of the white light exit from the fourth sub-pixel with the normalized spectrum of the reference white point that, the spectrum of the white light exit from the fourth sub-pixel and the normalized spectrum of the reference white point coincide substantially. In this case, in order to achieve the pixel reflectivity of the fourth sub-pixel close to the pixel reflectivity of the first sub-pixel, the pixel reflectivity of the second sub-pixel and the pixel reflectivity of the third sub-pixel, as shown in FIG. 10 or 11, the fourth filter portion 34 may be set to further include a fourth filter sub-portion 343 in addition to the first filter sub-portion 341 and the second filter sub-portion 342. The light exit from the fourth filter sub-portion 343 has the same color as the light exit from the third filter portion 33.

In this way, the provision of the first filter sub-portion 341, the second filter sub-portion 342 and the fourth filter sub-portion 343 may avoid affecting an effect of the white light exit from the fourth sub-pixel, so as to ensure that the spectrum of the white light exit from the fourth sub-pixel approximately coincides with the normalized spectrum of the reference white point, and ensure that the pixel reflectivity of the fourth sub-pixel is close to the pixel reflectivity of the first sub-pixel, the pixel reflectivity of the second sub-pixel and the pixel reflectivity of the third sub-pixel, thereby ensuring the display effect of the display panel.

The first filter sub-portion 341, the second filter sub-portion 342 and the fourth filter sub-portion 343 may be arranged in the same layer as shown in FIG. 10, or may be arranged in stacked layers as shown in FIG. 11. Of course, any two of the three filter sub-portions may be arranged in stacked layers. For example, the first filter sub-portion 341, the second filter sub-portion 342 and the fourth filter sub-portion 343 are respectively a green filter sub-portion, a red filter sub-portion and a blue filter sub-portion. In this case, the first filter sub-portion 341 is disposed in the same layer as the second filter portion 32, the second filter sub-portion 342 is disposed in the same layer as the first filter portion 31, and the fourth filter sub-portion 343 is disposed in the same layer as the third filter portion 33.

In a case where the first filter sub-portion 341, the second filter sub-portion 342 and the fourth filter sub-portion 343 are distributed in the same layer, an area of each filter sub-portion determines a filtering effect of the filter sub-portion on light. In combination with the above case where the first filter sub-portion 341, the second filter sub-portion 342 and the fourth filter sub-portion 343 are respectively a green filter sub-portion, a red filter sub-portion and a blue filter sub-portion, in order to prevent the arrangement of the first filter sub-portion 341, the second filter sub-portion 342 and the fourth filter sub-portion 343 from affecting the effect of the white light exit from the fourth sub-pixel, an area ratio of regions of the first filter sub-portion 341, the second filter sub-portion 342 and the fourth filter sub-portion 343 is set according to a color ratio of red, green and blue. For example, the area ratio of the regions of the first filter sub-portion 341, the second filter sub-portion 342 and the fourth filter sub-portion 343 may be set to 7:2:1. Alternatively, the area ratio of the regions of the first filter sub-portion 341, the second filter sub-portion 342 and the fourth filter sub-portion 343 may be set to 6:3:1.

In a case where the first filter sub-portion 341, the second filter sub-portion 342 and the fourth filter sub-portion 343 are distributed in stacked layers, a thickness of each filter sub-portion determines a filtering effect of the filter sub-portion on light. In combination with the above case where the first filter sub-portion 341, the second filter sub-portion 342 and the fourth filter sub-portion 343 are respectively a green filter sub-portion, a red filter sub-portion and a blue filter sub-portion, in order to prevent the arrangement of the first filter sub-portion 341, the second filter sub-portion 342 and the fourth filter sub-portion 343 from affecting the effect of the white light exit from the fourth sub-pixel, a thickness ratio of regions of the first filter sub-portion 341, the second filter sub-portion 342 and the fourth filter sub-portion 343 is set according to a color ratio of red, green and blue. For example, the thickness ratio of the first filter sub-portion 341, the second filter sub-portion 342 and the fourth filter sub-portion 343 may be set to 7:2:1. Alternatively, the thickness ratio of the first filter sub-portion 341, the second filter sub-portion 342 and the fourth filter sub-portion 343 may be set to 6:3:1.

In the embodiments of the present disclosure, in combination with the above description, the light-emitting portion included in the light-emitting layer 2 may have a top-emission structure or a bottom-emission structure. Then, the explanation is made by considering an example of the top-emission.

In combination with the above description, the first filter portion 31 corresponds to the first light-emitting portion 21, the second filter portion 32 corresponds to the second light-emitting portion 22, the third filter portion 33 corresponds to the third light-emitting portion 23, and the fourth filter portion 34 corresponds to the fourth light-emitting portion 24. In this case, the reflectivity of the reflective anode 215 included in the first light-emitting portion 21, the reflectivity of the reflective anode 215 included in the second light-emitting portion 22, the reflectivity of the reflective anode 215 included in the third light-emitting portion 23, and the reflectivity of the reflective anode 215 included in the fourth light-emitting portion 24 may be the same, that is, the reflective anode 215 of each of the plurality of light-emitting portions included in the light-emitting layer 2 has the same material. For example, the reflective anode 215 included in the first light-emitting portion 21, the reflective anode 215 included in the second light-emitting portion 22, the reflective anode 215 included in the third light-emitting portion 23, and the reflective anode 215 included in the fourth light-emitting portion 24 are all composite layers of silver and indium tin oxide, or composite layers of nickel-aluminum alloy and indium tin oxide.

Of course, the reflectivity of the reflective anode 215 included in the first light-emitting portion 21, the reflectivity of the reflective anode 215 included in the second light-emitting portion 22, and the reflectivity of the reflective anode 215 included in the third light-emitting portion 23 may also be set to be greater than the reflectivity of the reflective anode 215 included in the fourth light-emitting portion 24, that is, the reflectivity of the reflective anode 215 corresponding to the first filter portion 31, the reflectivity of the reflective anode 215 corresponding to the second filter portion 32, and the reflectivity of the reflective anode 215 corresponding to the third filter portion 33 are all greater than the reflectivity of the reflective anode 215 corresponding to the fourth filter portion 34.

In this way, the setting of the reflectivity of the first light-emitting portion 21, the reflectivity of the second light-emitting portion 22 and the reflectivity of the third light-emitting portion 23 being greater than the reflectivity of the fourth light-emitting portion 24 may reduce the pixel reflectivity of the fourth sub-pixel. On a basis of ensuring the full-color display of the display panel, the light-emitting effects of the first sub-pixel, the second sub-pixel, the third sub-pixel and the fourth sub-pixel may be made close, thereby ensuring the display effect of the display panel.

Optionally, the reflectivity of the reflective anode 215 included in the first light-emitting portion 21, the reflectivity of the reflective anode 215 included in the second light-emitting portion 22, and the reflectivity of the reflective anode 215 included in the third light-emitting portion 23 may be the same. For example, the reflective anode 215 corresponding to the first filter portion 31, the reflective anode 215 corresponding to the second filter portion 32, and the reflective anode 215 corresponding to the third filter portion 33 are all composite layers of silver and indium tin oxide, or composite layers of nickel-aluminum alloy and indium tin oxide. The reflectivity of the reflective anode 215 included in the fourth light-emitting portion 24 is less than the reflectivity of the reflective anode 215 included in the first light-emitting portion 21. For example, the reflective anode 215 corresponding to the fourth filter portion 34 is a composite layer of molybdenum and indium tin oxide.

Embodiments of the present disclosure provide a method for manufacturing a display panel, and the method is used to manufacture the display panel as mentioned in the above embodiments. The method includes the following steps S110 to S120.

In step S110, a light-emitting layer is formed, where the light-emitting layer includes a plurality of light-emitting portions distributed in an array, and the plurality of light-emitting portions include at least a light-emitting portion for emitting white light.

In step S120, a filter layer is formed on a light-exit side of the light-emitting layer, where the filter layer includes a plurality of filter portions corresponding one-to-one to the plurality of light-emitting portions.

The plurality of filter portions include a first filter portion, a second filter portion, a third filter portion and a fourth filter portion, and a light-emitting portion corresponding to the fourth filter portion emits the white light. In a direction perpendicular to the display panel, the first filter portion, the second filter portion and the third filter portion all cover the corresponding light-emitting portions, and the fourth filter portion at least partially overlaps with the corresponding light-emitting portion. The first filter portion is configured to allow a first color light to exit, the second filter portion is configured to allow a second color light to exit, the third filter portion is configured to allow a third color light to exit, and the fourth filter portion is configured to allow white light to exit.

Furthermore, before step S110, the method further includes providing a base substrate. Then, in step S110, the light-emitting layer may be formed on a side of the base substrate. Step S120 further includes: forming a light-shielding layer on a light-exit side of the light-emitting layer, where the light-shielding layer is distributed between two adjacent filter portions.

The display panel manufactured by the manufacturing method provided in the present disclosure may achieve full-color display through the first sub-pixel, the second sub-pixel, the third sub-pixel and the fourth sub-pixel. Moreover, the fourth filter portion included in the fourth sub-pixel may reduce the pixel reflectivity of the fourth sub-pixel. Thus, the pixel reflectivity of the fourth sub-pixel is close to the pixel reflectivity of the first sub-pixel, the pixel reflectivity of the second sub-pixel and the pixel reflectivity of the third sub-pixel. That is, the light-emitting effects of the first sub-pixel, the second sub-pixel, the third sub-pixel and the fourth sub-pixel are made close, thereby ensuring the display effect of the display panel.

It should be noted that the above contents describe various steps in the method for manufacturing the display panel in the present disclosure in a specific order. However, it does not require or imply that these steps need to be performed in the specific order or that all the steps shown need to be performed to achieve the desired results. Additionally or alternatively, some steps may be omitted, multiple steps may be combined into a step, and/or a step may be decomposed into multiple steps.

The embodiments of the present disclosure further provide a display device, and the display device includes the display substrate as described in the above embodiments.

In the present disclosure, in combination with the display panel described above, the provision of the fourth filter portion that has an overlap region with the fourth light-emitting portion may make the light-emitting effects of the first sub-pixel, the second sub-pixel, the third sub-pixel and the fourth sub-pixel close, thereby ensuring the full-color display effect of the display device.

Other embodiments of the present disclosure will be easily conceived of by those skilled in the art in consideration of the specification and practicing the invention disclosed here. The present disclosure is intended to cover any variations, uses or adaptations of the present disclosure. These variations, uses, or adaptations follow the general principles of the present disclosure and include common knowledge or conventional technical means in the art which is not disclosed in the present disclosure. The specification and the embodiments are only regarded as exemplary, and the true scope and spirit of the present disclosure are set forth according to the claims.

What is claimed is:

1. A display panel, comprising:
a light-emitting layer including a plurality of light-emitting portions distributed in an array, the plurality of light-emitting portions including at least a light-emitting portion for emitting white light; and
a filter layer located on a light-exit side of the light-emitting layer and including a plurality of filter portions corresponding one-to-one to the plurality of light-emitting portions; wherein
the plurality of filter portions include a first filter portion, a second filter portion, a third filter portion and a fourth filter portion, and a light-emitting portion corresponding to the fourth filter portion is for emitting the white light; in a direction perpendicular to the display panel, the first filter portion, the second filter portion and the third filter portion all cover corresponding light-emitting portions, and the fourth filter portion at least partially overlaps with a corresponding light-emitting portion; the first filter portion is configured to allow a first color light to exit, the second filter portion is configured to allow a second color light to exit, the third filter portion is configured to allow a third color light to exit, and the fourth filter portion is configured to allow the white light to exit.

2. The display panel according to claim 1, wherein the fourth filter portion includes a first filter sub-portion, and light exit from the first filter sub-portion has a same color as light exit from the second filter portion.

3. The display panel according to claim 2, wherein the first filter sub-portion is disposed in a same layer and made of a same material as the second filter portion.

4. The display panel according to claim 2, wherein in a case where a ratio of an area of the first filter sub-portion to an area of a light-emitting region of the light-emitting portion corresponding to the fourth filter portion is greater than or equal to a reference value, a thickness of the first filter sub-portion is less than a thickness of the second filter portion; and
in a case where the ratio of the area of the first filter sub-portion to the area of the light-emitting region of the light-emitting portion corresponding to the fourth filter portion is less than the reference value, the thickness of the first filter sub-portion is greater than or equal to the thickness of the second filter portion.

5. The display panel according to claim 2, wherein the fourth filter portion further includes a second filter sub-portion, and light exit from the second filter sub-portion has a same color as light exit from the first filter portion; and the first filter sub-portion and the second filter sub-portion are distributed in a same layer or in stacked layers.

6. The display panel according to claim 1, wherein the fourth filter portion includes a third filter sub-portion, and light exit from the third filter sub-portion has a same color as mixed light of light exit from the first filter portion and light exit from the second filter portion.

7. The display panel according to claim 6, wherein in a case where a ratio of an area of the third filter sub-portion to an area of a light-emitting region of the light-emitting portion corresponding to the fourth filter portion is greater than or equal to a reference value, a thickness of the third filter sub-portion is less than a thickness of the first filter portion and less than a thickness of the second filter portion; and
in a case where the ratio of the area of the third filter sub-portion to the area of the light-emitting region of the light-emitting portion corresponding to the fourth filter portion is less than the reference value, the thickness of the third filter sub-portion is greater than or equal to the thickness of the first filter portion and greater than or equal to the thickness of the second filter portion.

8. The display panel according to claim 5, wherein the fourth filter portion further includes a fourth filter sub-portion, and light exit from the fourth filter sub-portion has a same color as light exit from the third filter portion; and the first filter sub-portion, the second filter sub-portion and the fourth filter sub-portion are distributed in the same layer, or at least two filter sub-portions are distributed in stacked layers.

9. The display panel according to claim 8, wherein the first filter portion, the second filter portion and the third filter portion are for emitting red light, green light and blue light, respectively.

10. The display panel according to claim 9, wherein an area ratio of the first filter sub-portion, the second filter sub-portion and the fourth filter sub-portion is 7:2:1.

11. The display panel according to claim 9, wherein a thickness ratio of the first filter sub-portion, the second filter sub-portion and the fourth filter sub-portion is 7:2:1.

12. The display panel according to claim 1, wherein the plurality of light-emitting portions include reflective anodes, and reflectivity of a reflective anode corresponding to the first filter portion, reflectivity of a reflective anode corresponding to the second filter portion and reflectivity of a reflective anode corresponding to the third filter portion are all greater than reflectivity of a reflective anode corresponding to the fourth filter portion.

13. The display panel according to claim 12, wherein the reflective anode corresponding to the first filter portion, the reflective anode corresponding to the second filter portion, and the reflective anode corresponding to the third filter portion are all composite layers of silver and indium tin oxide or all composite layers of nickel-aluminum alloy and indium tin oxide, and the reflective anode corresponding to the fourth filter portion is a composite layer of molybdenum and indium tin oxide.

14. A display device, comprising the display panel according to claim 1.

15. The display panel according to claim 1, wherein the plurality of light-emitting portions include a first light-emitting portion corresponding to the first filter portion, a second light-emitting portion corresponding to the second filter portion, a third light-emitting portion corresponding to the third filter portion, and a fourth light-emitting portion corresponding to the fourth filter portion; and the fourth light-emitting portion is configured to emit the white light.

16. The display panel according to claim 1, wherein each light-emitting portion includes an anode, a light-emitting functional layer and a cathode; and
a light-emitting functional layer included in the light-emitting portion for emitting the white light has a film layer structure in which a red functional layer, a green functional layer and a blue functional layer are stacked in sequence; or a light-emitting functional layer included in the light-emitting portion for emitting the white light has a film layer structure in which a blue functional layer, a red functional layer, a yellow functional layer and a blue functional layer are stacked in sequence.

17. The display panel according to claim 1, further comprising a light-shielding layer, wherein the light-shielding layer is located in a same layer as the filter layer, and the light-shielding layer is distributed between two adjacent filter portions to separate the plurality of filter portions.

18. The display panel according to claim 1, further comprising a thin film encapsulation layer, wherein the thin film encapsulation layer is disposed on a side of the filter layer proximate to the light-emitting layer, or on a side of the filter layer away from the light-emitting layer; and the thin film encapsulation layer includes an inorganic encapsulation layer, an organic encapsulation layer and an inorganic encapsulation layer that are disposed alternately.
